(19) United States
(12) Patent Application Publication
(10) Pub. No.: US 2014/0354127 A1
(43) Pub. Date: Dec. 4, 2014

(54) HANDLE ASSEMBLY AND ELECTRONIC DEVICE CHASSIS HAVING THE SAME

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: RI-DONG HUANG, Wuhan (CN); CHEN-LIANG HUANG, New Taipei (TW); GUANG-YAO LEE, New Taipei (TW)

(73) Assignees: HONG FU JIN PRECISION INDUSTRY (WuHan) CO., LTD., Wuhan (CN); HON HAI PRECISION INDUSTRY CO., LTD., New Taipei (TW)

(21) Appl. No.: 13/928,195

(22) Filed: Jun. 26, 2013

(30) Foreign Application Priority Data
Jun. 3, 2013 (CN) 2013102154512

(51) Int. Cl. H05K 5/02; B25G 3/38

(52) U.S. Cl. CPC H05K 5/023; B25G 3/38; H05K 5/0221; H05K 5/0256
USPC 312/244; 16/110.1

(57) ABSTRACT

A handle assembly includes a fixing member, a latching member received in the fixing member, and a handle slidably mounted to the fixing member. The latching member includes two resilient arms at opposite ends. Each resilient arm includes a projection. The handle includes a hold portion and two legs extending down from opposite ends of the hold portion. Each leg defines an engaging hole. The hold portion is pressed toward the fixing member, and the projections are engaged in the engaging holes.

### BACKGROUND

1. Technical Field

The present disclosure relates to a chassis of an electronic device including a handle.

2. Description of Related Art

Most electronic devices, such as computers, have enclosures to contain electronic elements. Because of the large weight and volume, it is inconvenient to move the enclosures.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a handle assembly; wherein the handle assembly includes a fixing member, a latching member, and two driving members.

FIG. 2 is an inverted view of FIG. 1.

FIG. 3 is an assembled view of the driving members and the fixing member of FIG. 2.

FIG. 4 is an assembled view of the driving members, the latching member, and the fixing member of FIG. 2.

FIG. 5 is an assembled view of FIG. 1.

FIGS. 6 to 8 are cross-sectional views showing different states of the handle assembly of FIG. 5 used in a chassis.

FIGS. 9 and 10 are cross-sectional views showing different using states of the handle assembly of FIG. 5.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

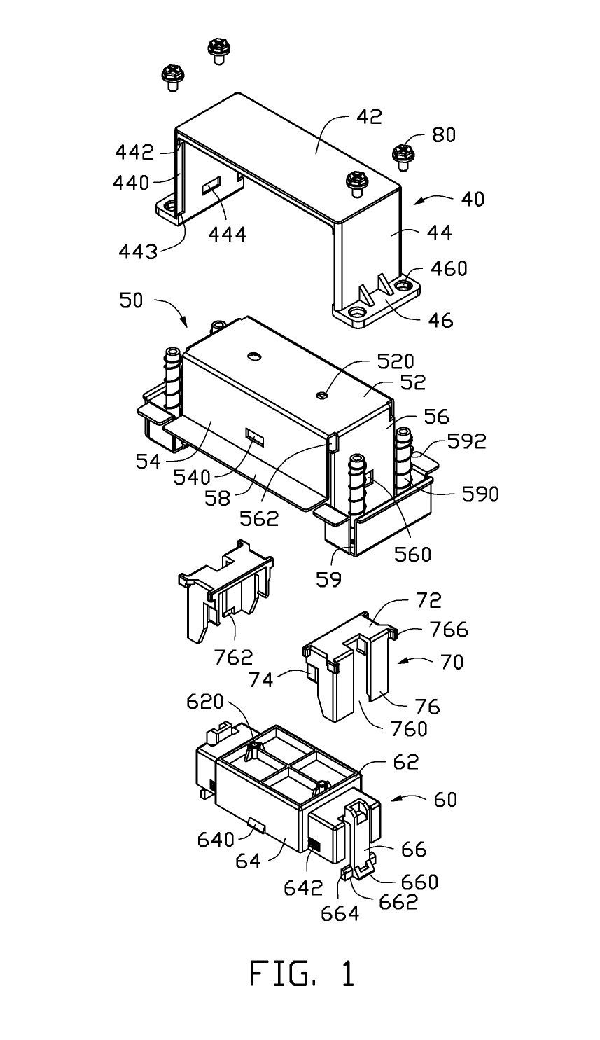

FIGS. 1, 2, and 6 show an embodiment of an electronic device chassis. The electronic device chassis includes a top board 10, an installation board 20 substantially parallel to the top board 10, and a handle assembly 30.

A receiving space 12 is bound by the top board 10 and the installation board 20. A receiving slot 14 communicating with the receiving space 12 is defined in each of the top board 10 and the installation board 20.

The handle assembly 30 includes a handle 40, a fixing member 50, a latching member 60, and two driving members 70.

The handle 40 includes a hold portion 42, two legs 44 extending down from opposite ends of the hold portion 42, and two installation pieces 46 extending substantially perpendicularly out from bottom ends of the legs 44. Two slide slots 440 substantially perpendicular to the hold portion 42 are defined in opposite sides of an inner surface of each leg 44. Each slide slot 440 includes a top end wall 442 adjacent to the hold portion 42, and a bottom end wall 443 adjacent to a corresponding installation piece 46. An engaging hole 444 is defined in the inner surface of each leg 44. Each installation piece 46 defines two through holes 460.

The fixing member 50 includes a connecting plate 52, two side plates 54 extending substantially perpendicularly down from opposite sides of the connecting plate 52, two end plates 56 extending substantially perpendicularly down from opposite ends of the connecting plate 52, two extension plates 58 extending substantially perpendicularly out from bottom sides of the side plates 54, and two fixing plates 59 extending substantially perpendicularly out from bottom ends of the end plates 56. Two positioning holes 520 are defined in the connecting plate 52. A positioning slot 540 is defined in each side plate 54. A through hole 560 is defined in each end plate 56. Two through holes 562 are defined in opposite sides of each end plate 56, adjacent to the connecting plate 52. Two posts 590 extend substantially perpendicularly up from each fixing plate 59. A spring 592 is fitted about each post 590.

The latching member 60 includes a top wall 62, two sidewalls 64 extending substantially perpendicularly down from opposite sides of the top wall 62, and two resilient arms 66 extending substantially perpendicularly down from opposite ends of the top wall 62. Two columnar protrusions 620 protrude up from the top wall 62. A wedge-shaped protrusion 640 protrudes out from each sidewall 64, away from the top wall 62. A plurality of recesses 642 is defined in each of opposite ends of an outer side of each sidewall 64, substantially perpendicular to the top wall 62. A wedge-shaped projection 660 protrudes out from a bottom end of each resilient arm 66. Two blocks 662 are connected to opposite ends of each projection 660. Each block 662 has a guiding surface 664 extending slantingly down from a top of the block 662 and away from the resilient arm 66.

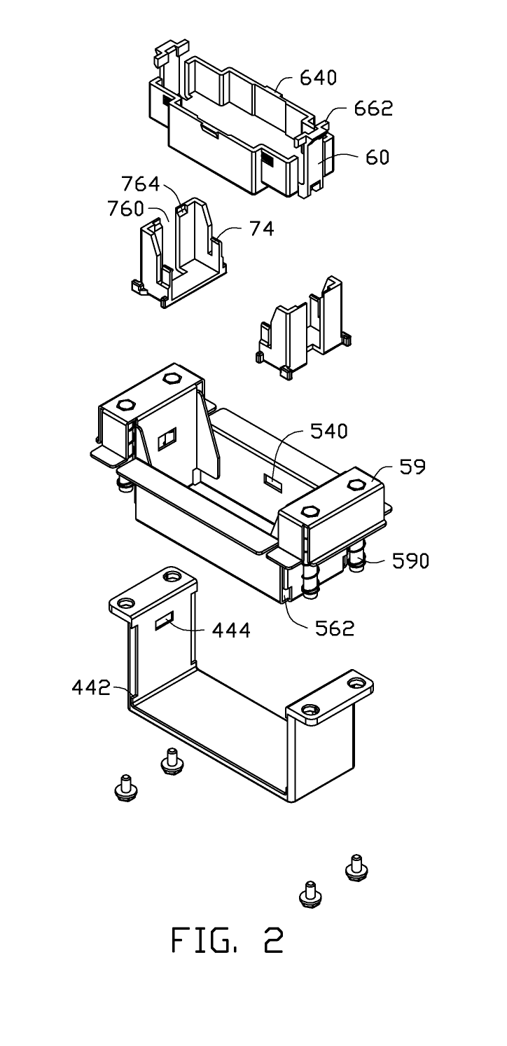

Each driving member 70 includes a connecting piece 72, two hooks 74 extending substantially perpendicularly down from opposite ends of the connecting piece 72, and a driving piece 76 extending substantially perpendicularly down from a side of the connecting piece 72. The driving piece 76 defines a through slot 760 extending through the connecting piece 72 and a bottom of the driving piece 76. Each driving piece 76 defines two depressed portions 762 in a bottom side of an inner surface of the driving piece 76 and at opposite sides of the through slot 760. Each depressed portion 762 includes a guiding surface 764 (shown in FIG. 2) extending slantingly down from a top of the depressed portion 762 toward the inner surface of the connecting piece 72. Two pins 766 protrude from opposite ends of a top side of each driving piece 76.

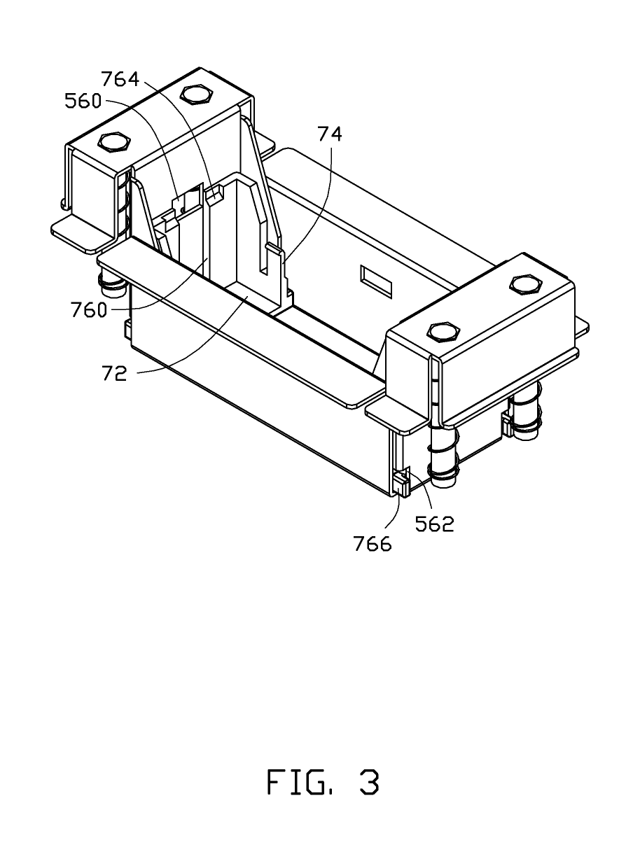

FIG. 3 shows that in assembly, the driving members 70 are received in the fixing member 50, with the pins 766 extending out of the fixing member 50 through the through holes 562.

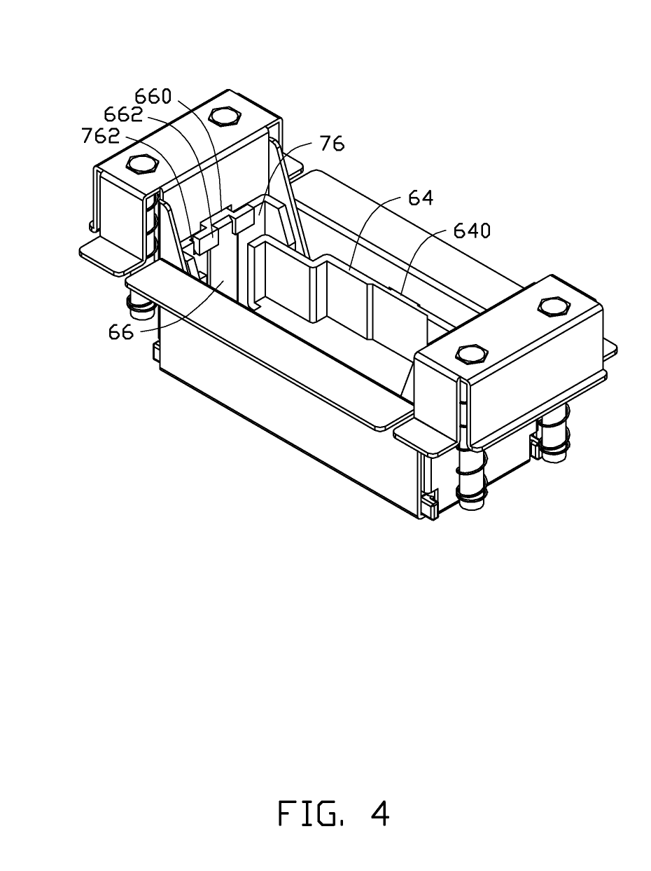

FIG. 4 shows that the latching member 60 is then received in the fixing member 50, sandwiches the driving members 70 together with the fixing member 50. The protrusions 620 are engaged in the positioning holes 520. The protrusions 640 are engaged in the positioning slots 540, thereby fixing the latching member 60 and the driving members 70 to the fixing member 50. The resilient arms 66 are received in the through slots 760, with the projections 660 extending out of the fixing member 50 through the through holes 560. The hooks 74 are correspondingly engaged in four recesses 642.

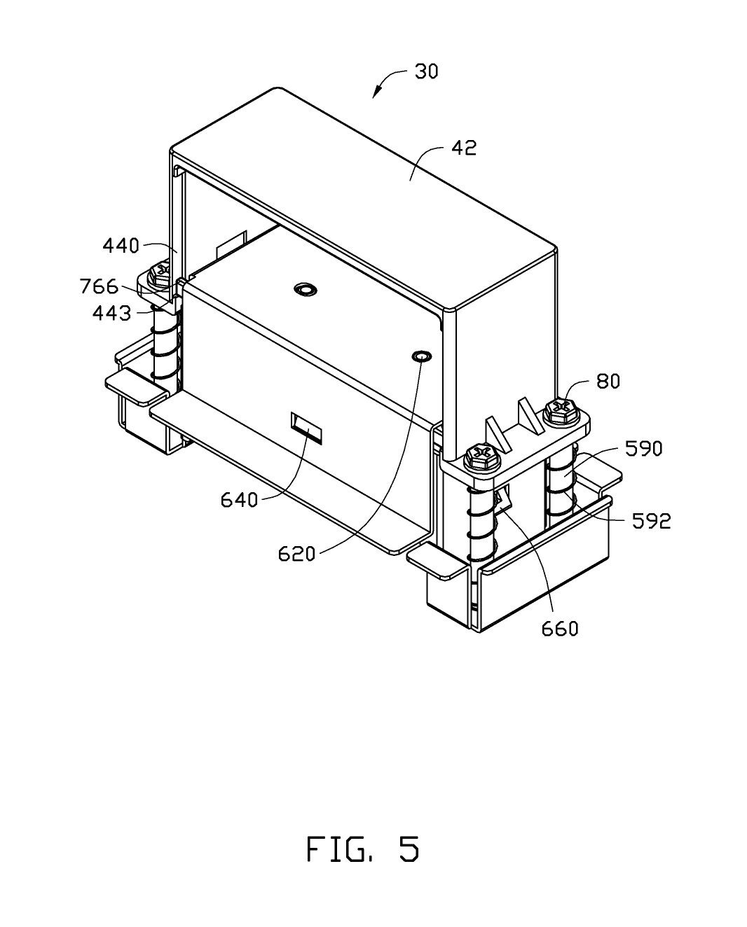

FIG. 5 shows four screws 80 extending through the through holes 460 and then are engaged in the posts 590, to movably mount the handle 42 to the fixing member 50 from top to bottom. Each spring 592 are resiliently sandwiched between the corresponding installation piece 46 and the corresponding fixing plate 59. The pins 766 are slidably received in the slide slots 440, but in an original state, the pins 766 are supported on the corresponding bottom end walls 443. The connecting pieces 72 are located above the top wall 62 for a distance.

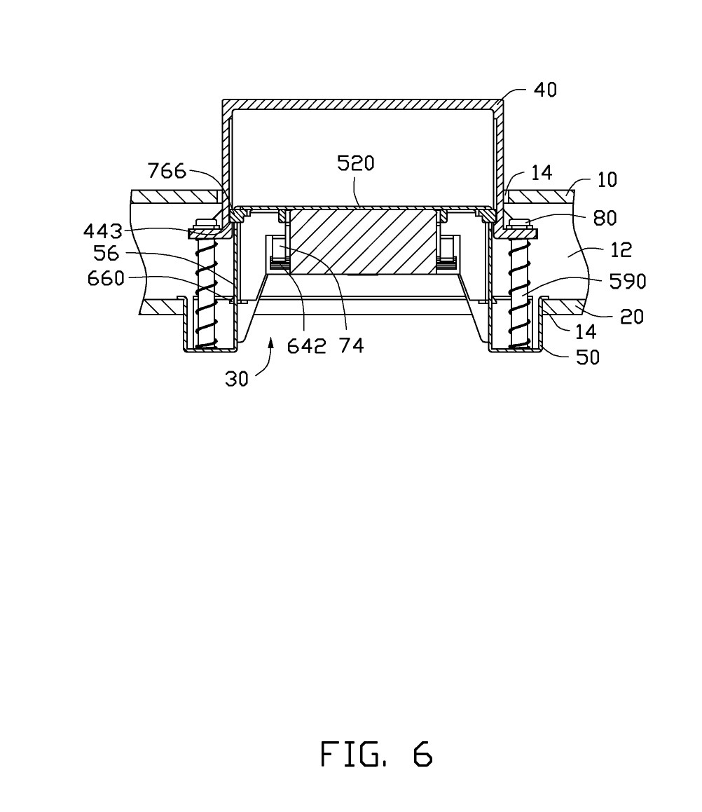

FIG. 6 shows that a lower portion of the fixing member 50 is received in the receiving slot 14 of the installation board 20, with the extension plates 58 contacting and fixed to a top of the installation board 20. At this time, an upper portion of the handle portion 40 extends out of the top board 10 through the receiving slot 14 of the top board 10.

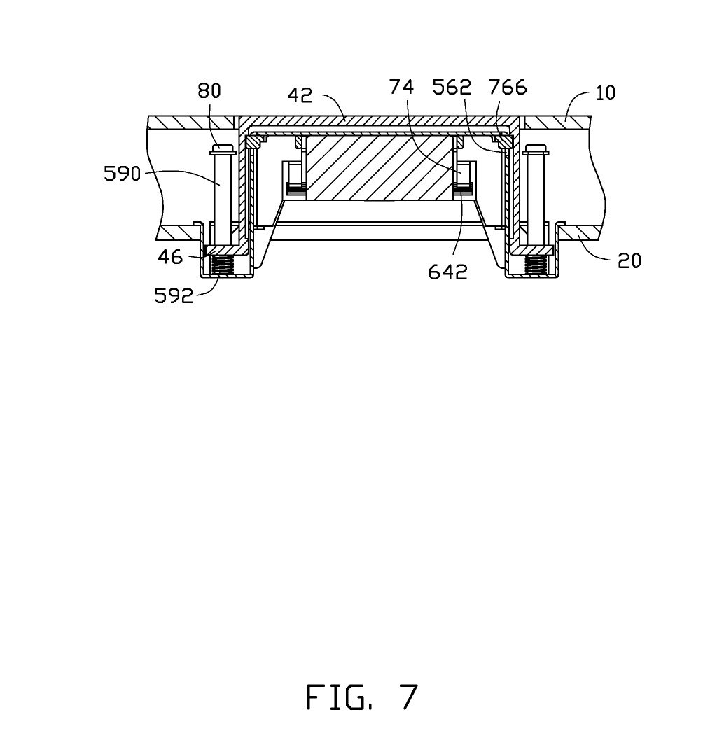

FIG. 7 shows that when the handle 40 is not used, the hold portion 42 is pressed down to deform the springs 592, until the hold portion 42 completely withdraws back in the receiving slot 14 of the top board 10. The projections 660 engage in the engaging holes 444, thereby fixing the handle 40. At this time, the pins 766 contact the corresponding top end walls 442. The distance between the connecting pieces 72 and the top wall 60 is not changed.

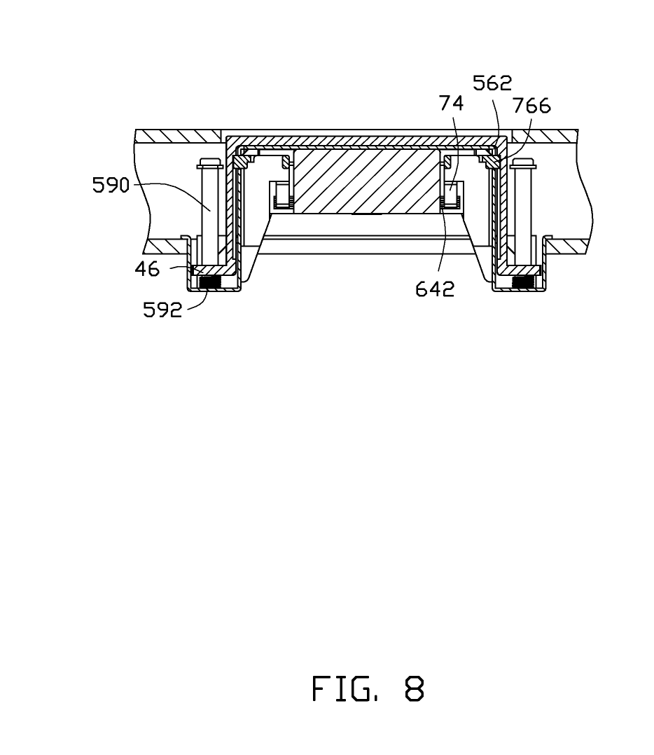

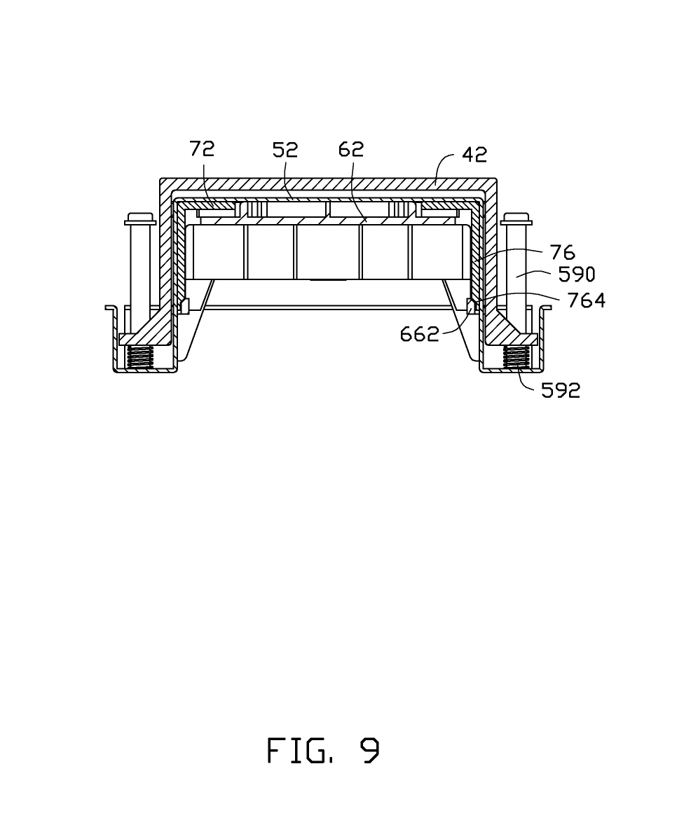

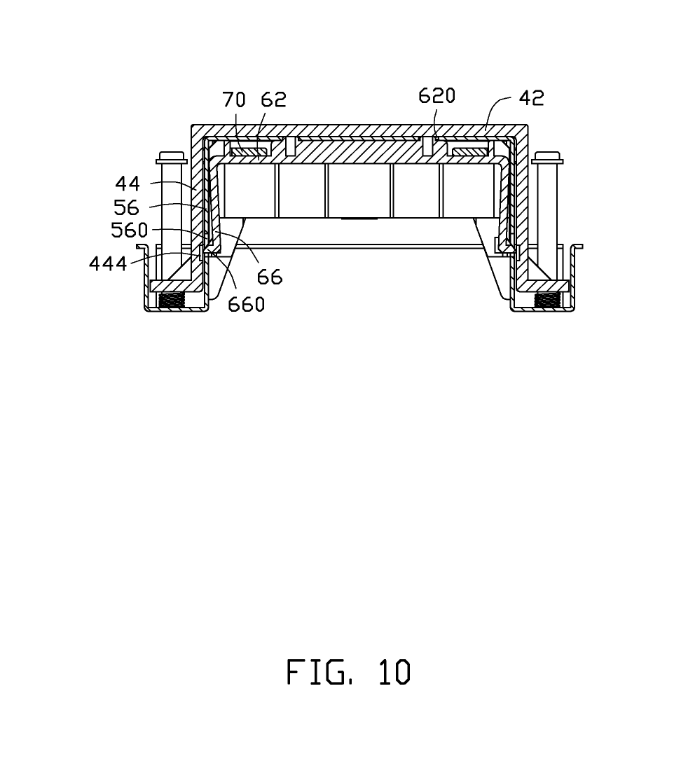

FIGS. 8 to 10 shows that if using the handle 40, the hold portion 42 is pressed down again, the top end walls 442 press the pins 766 down, thereby moving the driving members 70 down. The distance between the connecting pieces 72 and the top wall 60 is decreased. The hooks 74 move down to engage in the corresponding lower recesses 642. The guiding surfaces 764 slide down along the corresponding guiding surfaces 664 and deform the resilient arms 76 toward the latching member 60, until the projections 660 disengage from the corresponding engaging holes 444. The hold portion 420 is then released. The springs 592 are restored and the handle 40 is pushed upward to expose out from the top board 10 through the receiving slot 14 of the top board 10.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A handle assembly, comprising:
a fixing member;
a latching member received in the fixing member and comprising two opposite resilient arms, each resilient arm comprising a projection extending through the fixing member; and
a handle slidably mounted to the fixing member, and comprising a hold portion and two legs connected to opposite ends of the hold portion, each leg defining an engaging hole;
wherein the hold portion is operable of being pressed to move toward the fixing member, the projections engaging in the engaging holes, thereby fixing the handle.

2. The handle assembly of claim 1, wherein the fixing member comprises a connecting plate, two side plates extending substantially perpendicularly down from opposite sides of the connecting plate, and two end plates extending substantially perpendicularly down from opposite ends of the connecting plate, each end plate defining a first through hole through which a corresponding projection extends.

3. The handle assembly of claim 2, wherein the handle further comprises two installation pieces extending out from bottom ends of the legs opposite to the hold portion, the fixing member further comprises two fixing plates extending out from bottom ends of the end plates opposite to the connecting plate, a post extends substantially perpendicularly up from each fixing plate, a spring fitted about each post, and two screws extending through the installation pieces and engaging in the posts, each spring being sandwiched between the installation piece and the fixing plate.

4. The handle assembly of claim 2, wherein the connecting plate defines a positioning hole, the latching member further comprises a top wall and a first protrusion protruding from the top wall of the latching member to be engaged in the positioning hole.

5. The handle assembly of claim 4, wherein the side plates each define a positioning slot, the latching member further comprises two sidewalls extending substantially perpendicularly down from opposite sides of the top wall, and a second protrusion protruding from each sidewall engaged in a corresponding positioning slot.

6. The handle assembly of claim 2, further comprising two driving members positioned between the fixing member and the latching member, wherein each driving member comprises a connecting piece, and a driving piece extending substantially perpendicularly down from a side of the connecting piece, each driving piece defining a through slot to receive a corresponding resilient arm.

7. The handle assembly of claim 6, wherein each driving member further comprises two hooks extending down from opposite sides of the connecting piece, the latching member comprises a top wall and two sidewalls extending down from opposite sides of the top wall, and each sidewall defines two rows of recesses in opposite ends to allow corresponding hooks to selectively engage in.

8. The handle assembly of claim 6, wherein each leg defines two slide slots substantially perpendicular to the hold portion in opposite sides of an inner surface the leg, each driving piece further comprises two pins protruding from opposite ends of a top side of the driving piece, each end plate defines two second through holes in opposite ends of a top side, and the pins extend through the second through holes and are slidably received in the slide slots.

9. The handle assembly of claim 8, wherein each slide slot includes a bottom end wall away from the hold portion to support a corresponding pin and maintain the connecting piece spaced from the top wall of the latching member.

10. The handle assembly of claim 9, wherein each slide slot further comprises a top end wall adjacent to the hold portion, each resilient arm further comprises two blocks connected to opposite ends of the corresponding projection, each block comprises a first guiding surface extending slantingly down and out from a top of the block, each driving piece defines two depressed portions in opposite ends of an inner side, each depressed portion comprises a second guiding surface extending slantingly down and in from a top surface of the depressed portion; when the hold portion is pressed down, the top end walls move down to press the pins to allow the second guiding surfaces to move down along corresponding first guiding surfaces, and deform the resilient arms toward each other, thereby disengaging the projections from the engaging holes.

11. A chassis, comprising:
a top board defining a receiving slot;
an installation board substantially parallel to the top board, and bounding a receiving space together with the top board;
a fixing member mounted to the installation board;
a latching member received in the fixing member and comprising two opposite resilient arms, each arm comprising a projection extending through the fixing member; and
a handle slidably relating to the fixing member and comprising a hold portion and two legs connected to opposite ends of the hold portion, each leg defining an engaging hole;
wherein when the hold portion is operable of being pressed to move toward the fixing member until the hold portion is withdraw in the receiving slot, the projections engage in the engaging holes, thereby fixing the handle.

12. The chassis of claim 11, wherein the fixing member comprises a connecting plate, two side plates extending substantially perpendicularly down from opposite sides of the connecting plate, and two end plates extending substantially perpendicularly down from opposite ends of the connecting plate, and each end plate defines a first through hole through which a corresponding projection extends.

13. The chassis of claim 12, wherein the handle further comprises two installation pieces extending out from bottom ends of the legs opposite to the hold portion, the fixing member further comprises two fixing pieces extending out from bottom ends of the end plates opposite to the connecting plate, a post extends substantially perpendicularly up from each fixing piece, a spring is fitted about each post, and two screws extend through the installation pieces and engage in the post, each spring being sandwiched between the installation piece and the fixing piece.

14. The chassis of claim 12, wherein the side plates each define a positioning slot, the latching member further comprises two sidewalls and a protrusion protruding from each sidewall engaging in a corresponding positioning slot.

15. The chassis of claim 12, further comprising two driving members positioned between the fixing member and the latching member, wherein each driving member comprises a connecting piece and a driving piece extending substantially perpendicularly down from a side of the connecting piece, each driving piece defining a through slot to receive a corresponding resilient arm.

16. The chassis of claim 15, wherein each driving member further comprises two hooks extending down from opposite sides of the connecting piece, the latching member comprises a top wall and two sidewalls extending down from opposite sides of the top wall, and each sidewall defines two rows of recesses in opposite ends to allow corresponding hooks to selectively engage in.

17. The chassis of claim 15, wherein each leg defines two slide slots substantially perpendicular to the hold portion in opposite sides of an inner surface of the leg, each driving piece further comprises two pins protrudes from opposite ends of a top side of the driving piece, each end plates defines two second through holes in opposite ends of a top side, the pins extend through the second through holes and are received in the slide slots, each slide slot includes a bottom end wall away from the holding portion to support a corresponding pin and maintain the connecting piece spaced from the top wall of the latching member.

18. The chassis of claim 17, wherein each slide slot further comprises a top end wall adjacent to the hold portion, each resilient arm further comprises two blocks connected to opposite ends of each projection, each block comprises a first guiding surface slantingly extending down and out from a top of the block, each driving piece defines two depressed portions in opposite ends of an inner side, each depressed portion comprising a second guiding surface extending slantingly down and in from a top surface of the depressed portion; when the hold portion is pressed down, the top end walls move down to press the pins to allow the second guiding surfaces to move down along the corresponding first guiding surfaces and deform the resilient arms toward each other, thereby disengaging the projections from the engaging holes.
